(19) United States
(12) Patent Application Publication
(10) Pub. No.: US 2009/0039714 A1
(43) Pub. Date: Feb. 12, 2009

(54) Magnetostrictive FeGa Alloys

(76) Inventors: Pinai Mungsantisuk, Salt Lake City, UT (US); Sivaraman Guruswanmy, Salt Lake City, UT (US); Nakorn Srisukhumbowornchai, Nakhonpathom (TH)

Correspondence Address: Workman Nydegger;1000 Eagle Gate Tower, 60 East South Temple, Salt Lake City, UT, 84111, US

(21) Appl. No.: 11/817,566

(22) PCT Filed: Mar. 3, 2006
(86) PCT No.: PCT/US2006/007786

§ 371 Date: Sep. 8, 2008

Related U.S. Application Data
(60) Provisional application No. 60/658,115, filed on Mar. 3, 2005.
(60) Provisional application No. 60/658,557, filed on Mar. 4, 2005.

(51) Int. Cl. H01L 41/12; C22C 38/00; C22C 38/12; H01L 41/20; C21D 8/00; C21D 1/00

(52) U.S. Cl. 310/26; 148/320; 148/337; 148/625; 148/579; 148/330

(57) ABSTRACT

A low-cost, thermomechanical method for manufacturing [001] textured FeGa alloys is described. The method includes hot rolling a FeGa cast ingot to break down the cast structure, a two-stage warm rolling with an intermediate anneal, and then a final texture anneal that resulted in recrystallization and a recrystallization-induced texture. The FeGa ingot contains a grain growth agent that was used to restrain grain growth of the FeGa material in the undesired crystallographic direction. A protective steel sheath can be placed around the FeGa material during processing to avoid direct contact of the FeGa and the rolls during the hot and warm rolling process steps and also avoid oxidation of the alloy ingot. FeGa alloys with a very strong [001] texture and a large magnetostriction along [001] crystallographic direction were obtained using this method. FeGaBe alloys and new methods for making them are also described.

### RELATED APPLICATIONS

This application claims priority of U.S. Provisional Application Ser. Nos. 60/658,115 and 60/658,557, the entire disclosures of which are incorporated herein by reference.

### FIELD

The invention generally relates to magnetostrictive materials. In particular, the invention relates to magnetostrictive FeGa alloys containing a grain growth control agent.

### BACKGROUND

Magnetostriction is the changing of the physical dimension of a material in response to a change in its magnetization. In other words, magnetostrictive materials will change shapes when subjected to a magnetic field. Since magnetostrictive materials change in dimension in response to an applied magnetic field, they have been used in sonar transducers, actuators, vibration controllers, sensors, and similar devices.

Most ferromagnetic materials exhibit some degree of magnetostriction and therefore yield magnetostrictions under relatively small magnetic fields. Thus, magnetostrictive materials typically contain ferromagnetic elements, such as iron and rare earth metals, or combinations of these elements. Examples of such materials are disclosed in U.S. Pat. No. 6,071,357, the disclosure of which is incorporated herein by reference, as well as alloys of iron with terbium (Tb) and dysprosium (Dy), including Terfenol-D. Terfenol-D, one of the most widely used magnetostrictive materials, has a large magnetostriction, but is brittle, requires large fields for saturation, and is expensive due to the high cost of the raw materials.

It has been previously known that enhancement of low field magnetostriction of iron (Fe) could be achieved by adding Ga. See U.S. patent application Ser. No. 10/182,095, the entire disclosure of which is incorporated herein by reference. See also N. Srisukhumbowornchai et al., Large Magnetostriction in DS FeGa and FeGaAl Alloys, 90 J. Appl. Phys. 5680-5688 (December 2001), Development of Highly Magnetostrictive FaGa, FeGaAl Alloys, N. Srisukhumbowornchai (Advisor: Prof. Guruswamy), PhD Dissertation, Univ. of Utah, pp. 1-199 (May 2001), S. Guruswamy et al., 43 Scripta Mater. 239-244 (2000); and N. Srisukhumbowornchai et al., 92 J. Appl. Phys., Vol. 5371-5379 (2002); the entire disclosures of which are incorporated herein by reference. Typically, the magnetostriction values were increased by adding Ga in a concentration of 15-27.5 at % Ga, which yielded an attractive combination of high mechanical strength, good ductility, ability to operate at high imposed stress levels and in a wide temperature range, all with relatively low cost.

Some of these FeGa alloys were obtained by directional solidification involving rapid heat extraction and by directional growth by seedless vertical Bridgman technique. The directionally grown alloy rods had a [001] texture and had good magnetostriction values at a composition of Fe-27.5 at. % Ga alloy. The highest magnetostriction values for these FeGa alloys were obtained when they were single crystals grown with a [001] orientation. Unfortunately, single crystal growth is expensive and the room temperature mechanical properties obtained were much less desirable than those properties obtained with polycrystalline alloys.

Accordingly, some of these FeGa alloys were made using an alternative method: a conventional thermomechanical processing involving hot rolling and a two-stage warm rolling, followed by texture annealing. This thermomechanical process provided thin sheets of stainless steel over an alloy ingot while hot rolling to prevent oxidation and Ga loss by vaporization. The sheets were peeled off after the hot rolling operation and the FeGa material was in direct contact with the roll faces during the warm rolling operation.

Thus, while the thermomechanical processing conditions for obtaining the [001] texture were identified, the [001] texture developed was not very strong. See, for example, N. Srisukhumbowornchai and S. Guruswamy, Crystallographic Textures In Rolled And Annealed Fe—Ga And Fe—Al Alloys, 35A Metallurgical Transactions 2963 (2004), the entire disclosure of which is incorporated herein by reference. As well, the process for forming these alloys had two other disadvantages. Though the rolls used in the rolling process were heated, there was some chilling of the FeGa surface due to the temperature difference between the roll surface and the FeGa material being rolled. Also, there were concerns regarding the alignment of the rolls and the non-uniformity of the thickness strain in the resulting FeGa alloy.

### SUMMARY

A low-cost, thermomechanical method for manufacturing [001] textured FeGa alloys is described. The method includes hot rolling a FeGa cast ingot to break down the cast structure, a two-stage warm rolling with an intermediate anneal, and then a final texture anneal that resulted in recrystallization and a recrystallization-induced texture. The FeGa ingot contains a grain growth control agent that was used to restrain grain growth of the FeGa material during hot rolling and develop the desirable crystallographic texture during the texture anneal. A protective steel sheath can be placed around the FeGa material during processing to avoid direct contact of the FeGa and the rolls during the hot and warm rolling process steps. FeGa alloys with a very strong [001] texture and a large magnetostriction along [001] crystallographic direction were obtained using this method. FeGaBe alloys and new methods for making them are also described.

### BRIEF DESCRIPTION OF THE DRAWINGS

The Figures are views of some aspects of the alloys and methods of making and using the alloys, in which:

FIG. 1 depicts a picture frame assembly used when rolling the alloys;

FIG. 2 illustrates the loads encountered when rolling the alloys;

FIGS. 3-8 depict the texture data of the alloys at various points in the processing of the alloys;

FIG. 9 shows SEM micrographs of the alloys at various points in the processing of the alloys; and

FIG. 10 illustrates one example of using the alloys.

The Figures presented in conjunction with this description are views of only particular—rather than complete—embodiments of the alloys and methods of making and using the alloys according to the invention. Together with the following description, the Figure demonstrates and explains the principles of the invention. In the Figure, the thickness of layers and regions are exaggerated for clarity. The same reference numerals in different drawings represent the same element, and thus their descriptions will be omitted.

### DETAILED DESCRIPTION

The following description provides specific details in order to provide a thorough understanding of the alloys and accompanying methods. The skilled artisan, however, would understand that the alloys and accompanying methods can be practiced without employing these specific details. Indeed, the illustrated alloys and methods can be modified and can be used in conjunction with apparatus and techniques conventionally used in the industry. For example, the methods could be used for any bee alloys comprising Fe—Al, Fe—Be, Fe—(Be,Al), FeGaBe, Fe(Ga,Be,Al) or FeGaAl.

The FeGa alloys can contain an effective amount of a grain growth control agent that facilitates development of a strong texture in the desired crystallographic orientation. Any known grain growth agent for FeGa alloys can be used, especially those that will dissolve at high temperatures. Examples of grain growth agents that can be used include carbide precipitates like, TiC, VC, and NbC, sulfides like MnS, and nitrides such as TiN, AlN, VN, and NbN, and carbonitrides like Nb(C,N), and borides such as TiB₂. In some aspects, NbC is used as the grain growth agent since it can be present as a distinct phase in a matrix of bcc Fe—Ga phase.

The amount of the grain growth agent that can be used in the alloys depends both on the type of agent used and on the amount needed to restrict the grain growth of the alloy during the processing. Typically, the amount of this agent can be more than about 1 mole %. For example, when the grain growth agent comprises NbC, the amount can range up to about 3 mole %. In some aspects of the alloys, the amount of NbC can range from about 0.75 to about 1.25 mole %. In yet other aspects, the amount of NbC is 1 mole %.

The amount of Ga present in the FeGa alloys depends on the enhancement needed in the magnetostriction of the alloy. The effects of Ga on the magnetostriction of Fe can vary depending on the concentration of Ga. To obtain the maximum magnetostriction, the concentration of Ga should be as high as possible without introducing significant concentrations of secondary phases and/or introduction of ordering that can lower the magnetostriction. As well, the concentration of Ga depends on how the alloy is formed. Numerically, the amount of Ga can range up to about 32.5 at % in the FeGa phase. In one aspect of the invention, the amount of Ga can range from about 3 to about 27.5 at % in the FeGa phase. In yet another aspect of the invention, the amount of Ga can be about 15 at %.

Other non-magnetic metals can also be added to the alloys. The non-magnetic metal can be substituted for Ga or can be added to the alloy in addition to Ga. Examples of other non-magnetic metals that can be added to the alloys include Be, Zn, Sn, Si, Ge, and Al. The amounts of the non-magnetic metals that can be added depends on which metal is added and whether the metal is substituted for, or added to, the Ga in the alloy. In some embodiments, the amounts of non-magnetic metals can range up to about 7.5 at % when used in combination with Ga and up to about 20 at % when used alone in the alloy.

In some embodiments, Be and/or Al can be used since their addition to the FeGa does not unduly decrease the magnetostriction. Substituting Ga with Al and/or Be can be made in FeGa alloys in certain composition ranges without a significant reduction in the magnetostriction. Indeed, minimal reductions in magnetostriction when Ga is partially substituted by the smaller Be or the larger Al atoms (relative to Fe atoms) in certain composition ranges indicates that the effects of Ga and Be can be additive.

The amounts of Al that can be used in the FeGa alloys can range up to about 17 at %. In some aspects, the amount of Al that can be used in the FeGa alloys can range from about 2.5 to about 17 at %. In other embodiments, the amount of Al that can be used in the FeGa alloys can range from about 5 to about 15 at %. Examples of the amounts of Al that can be used, as well as their accompanying magnetostriction values, are set forth in Table 1.

The amounts of Be that can be used in the FeGa alloys can range up to about 25% at %. In some aspects, the amount of Be that can be used in the FeGa alloys can range from about 2.5 to about 22.5 at %. In other embodiments, the amount of Be that can be used in the FeGa alloys can range from about 5 to about 15 at %. Examples of the amounts of Be that can be used, as well as their accompanying magnetostriction values, are set forth in Table 1.

As can be seen in Table 1, a partial substitution of Ga with Be for certain FeGa alloys can be made without a significant drop in magnetostriction. For example, with Fe-20 at % Ga alloys, Be substitution for Ga can be made up to 7.5 at. % Be while maintaining high magnetostriction values. Indeed, the high magnetostriction values that were obtained for these specific alloys were comparable to the magnetostriction values in Fe-15% Ga alloys, and were also similar to those values obtained for Al substitutions. Thus, little to no reduction in the magnetostriction is experienced when Ga is partially substituted by Be suggests that the contribution to magnetostriction of Fe by Ga and Be in these ternary alloys are additive.

TABLE I
Magnetostriction data of FeGaAl and FeGaBe Alloys

| | Magnetostriction (×10⁻⁶) | | | | | |
|---|---|---|---|---|---|---|
| | For Different Compressive Stress | | | | | |
| | Levels (MPa) | | | | | |
| Alloy Composition | 0 | 5 | 10 | 20 | 30 | 50 |
| Fe—15 at. % Ga* | 170 | — | 163 | 182 | 196 | 155^{†} |
| Fe—12.5 at. % Ga—2.5 at. | 214 | 179 | 179 | 178 | 179 | 177 |
| % Al | | | | | | |
| Fe—10 at. % Ga—5 at. % Al | 27 | 79 | 68 | 107 | 129 | 111 |
| Fe—5 at. % Ga—10 at. % Al | 81 | 92 | 89 | 84 | 85 | 88 |
| Fe—15 at. % Al | 35 | 60 | 42 | 50 | 51 | 51 |
| Fe—20 at. % Ga* | 228 | 219 | 214 | 204 | — | 180^{†} |
| Fe—17.5 at. % Ga—2.5 at. | 204 | 206 | 215 | 220 | 234 | 230 |
| % Al | | | | | | |
| Fe—12.5 at. % Ga—7.5 at. | 207 | 232 | 233 | 237 | 239 | 236 |
| % Al | | | | | | |
| Fe—10 at. % Ga—10 at. | 172 | 200 | 205 | 208 | 211 | 202 |
| % Al | | | | | | |
| Fe—7.5 at. % Ga—12.5 at. | 42 | 141 | 143 | 141 | 138 | 136 |
| % Al | | | | | | |
| Fe—3 at. % Ga—17 at. % Al | 66 | 64 | 78 | 101 | 96 | 102 |
| Fe—27.5 at. % Ga* | 259 | 271 | 253 | 241 | — | 233^{†} |
| Fe—24 at. % Ga—3.5 at. % | 118 | 139 | 152 | 165 | 174 | 173 |
| Al | | | | | | |
| Fe—20.625 at. % Ga—6.875 | 157 | 164 | 184 | 177 | 151 | 138 |
| at. % Al | | | | | | |
| Fe—17.5 at. % Ga—10 at. % | 127 | 140 | 152 | 163 | 153 | 137 |
| Al | | | | | | |
| Fe—13.75 at. % Ga—13.75 | 116 | 141 | 132 | 127 | 124 | 119 |
| at. % Al | | | | | | |
| Fe—17.5 at. % Ga—2.5 at. | 122 | 153 | 165 | 184 | 195 | 216 |
| % Be | | | | | | |
| Fe—12.5 at. % Ga—7.5 at. | 179 | 193 | 194 | 181 | 173 | 163 |
| % Be | | | | | | |

^{†}At 40 MPa

Other details about including Al and Be in the FeGa alloys are described in Pinai Mungsantisuk et al., Influence of Be and Al on the Magnetostrictive Behavior of FeGa Alloys, 98 J. Appl. Phys. 123907 (2005) and P. Mungsantisuk, Ph.D. Dissertation, University of Utah, Salt Lake City, Utah (2005), the entire disclosures of which are incorporated herein by reference.

The FeGa alloys can contain impurities and other metals that do not significantly lower the magnetostriction of the alloy. Examples of impurities that typically can be present include C, N, H, Si, Mn, and B. Examples of other metals that typically can be present include Co and Ni. The concentration of the impurities and other metals typically range up to about 2 at %, and in some aspects, up to about 1 at %.

Thus, in some embodiments, the alloys can be represented by the formula (Fe_{100-x-y-z}GaₓAl_{y}Be_{z})ₐ (NbC)_{b} where x≦32.5, y≦17, z≦25, a≧97, and b≦3 (provided that “≦” would include also amounts about the same as the number it modified). In other embodiments, the alloys can be represented by the formula (Fe_{100-x-y-z}GaₓAl_{y}Be_{z})ₐ (NbC)_{b} where 2.5≦x≦30, 2.5≦y≦17, 2.5≦z≦22.5, 97≦a≦99.75, and 0.25≦b≦3. In still other embodiments, the alloys can be represented by the formula (Fe_{100-x-y-z}GaₓAl_{y}Be_{z})ₐ (NbC)_{b} where 5≦x≦27.5, 5≦y≦15, 5≦z≦15, 97≦a≦99, and 1≦b≦3.

The FeGa alloys have several unique properties. In particular, the magnetostriction of the alloys, as measured along the [100] axis at room temperature, can be at least about 200 ppm. In one aspect of the invention, the magnetostriction can be at least about 250 ppm. In yet another aspect of the invention, the magnetostriction can be at least about 300 ppm and, in some instances, as high as 400 ppm. With lower magnetostrictions, a wider range of alloy compositions can be used.

Another property of the FeGa alloys comprises an increased strength in the [001] texture. As noted above, the prior FeGa alloys had a weak strength, for example, a Vickers hardness of about 4.4 The FeGa alloys described herein have an improved relative strength of more than about 5. In some aspects, this improved strength can be more than about 33. In some aspects, this improved strength can range from about 20 to about 40. Another property of the improved thermomechanical process for FeGa alloys comprises an increased uniformity in the thickness strain as the surface chilling effect is avoided by the presence of stainless steel sheath through the warm rolling process.

Another improvement in the thermomechanical process for the FeGa alloys comprises use of large industrial scale furnaces with a stable temperature control, use of well aligned rolling mills, larger and well controlled amount of deformation per pass, and controlled reheating between passes. All of these improvements led to predictable and uniform deformation during the warm rolling process.

The FeGa alloys described above can be made by any process that provides the alloys with the characteristics and properties described above. See, for example, S. Guruswamy et al., Deformation Behavior and Texture Development During the Thermomechanical Processing of Fe-15At % Ga Alloys Containing NbC, “Trends in Materials and Manufacturing Technologies For Transportation Industries and PM Research and Development in the Transportation Industry” MPMD Sixth Global Innovations Symposium Proceedings, TMS Annual Meeting 2005 (San Francisco), pp 183-192. In some aspects, the methods described below can be used in the invention. Examples of other methods that can be used include directional growth methods like the Bridgman method.

The method begins by providing a FeGa alloy with the desired amount of the grain growth control agent. Any known method for providing the alloy with the desired amount of the grain growth control agent can be used in the invention. Where NbC is used, the desired amount of grain growth control agent can be provided in the FeGa alloy by melting the desired amounts of Fe, Ga, Nb, and C together to form an ingot, and then precipitating the desired amount of the NbC into the ingot.

The alloys can then be provided with a protective sheath. In some aspects, the sheath is provided by encasing the alloy ingot in a machined picture-frame assembly, which is sealed sealing and evacuated. The sheath is placed around the FeGa material to avoid oxidation of the ingot and also direct contact of the FeGa and the rolls during the subsequent hot and warm rolling process steps. The sheath also allows the strain through the thickness of the FeGa material to be more uniform and minimize the influence of chilling during the hot and warm rolling operations that arises from the heat extraction by the contacting roll surface. Any sheath that meets these criteria, protects the FeGa material during the process without reacting, alloying, or otherwise interacting with the FeGa. The sheath material also needs to have sufficient ductility and deformation characteristics matching that of the ingot material. Examples of materials that can be used in the sheath include stainless steel, mild steel, nickel alloys, and combinations thereof. The thickness of the sheath depends on the material used, as well as ingot dimensions and the rolling temperature. Generally, the thickness of the sheath can range from about 2 to about 4 mm. Where stainless steel is used, the thickness of the sheath can be about 3.25 mm.

The method continues by subjecting the FeGa alloy to a hot rolling process. The hot rolling process breaks down the cast structure of the alloy. Thus, any hot rolling process that serves this function can be used in invention. In one aspect of the invention, the hot rolling process is performed at a temperature ranging from about 1050 to about 1200° C. In another aspect of the invention, the hot rolling process is performed at a temperature of about 1150° C.

During the hot rolling, the grain growth control agent forms a precipitate that controls the grain size, which in turn impacts deformation and microstructure development during warm rolling and subsequent annealing. The dispersion also impacts the deformation and the development of the texture.

The next step of the method comprises a warm rolling process during which the alloy develops a strong deformation induced texture. Any warm rolling process that serves this function can be used in the invention. In one aspect of the invention, the warm rolling process comprises a two-stage warm rolling process. In this aspect of the invention, both stages of the warm rolling process are performed at a temperature ranging from about 350 to about 550° C. In another aspect of the invention, both stages of the warm rolling process are performed at a temperature of about 400° C.

An intermediate annealing step is carried out between the two warm rolling steps to avoid the development of cracks and to have finer grained and a textured starting material for the second stage warm rolling operation. Large deformation in a single stage of rolling leads to cracking of the material. Intermediate anneal leads recrystallization, refinement of grains, and the restoration of ductility of the alloy to near pre-deformation levels. Generally, the annealing process is performed for about 2 to about 1 hour at a temperature of about 800 to about 1000° C. In one aspect of the invention, the annealing process is performed for about 60 minutes at a temperature of about 900° C.

During all of the rolling processes, the operating conditions were carefully controlled. For example, the alignment of the rolls used were performed by skilled technicians and the temperature of sheathed ingot assembly was carefully controlled by the use of large industrial scale furnaces with a stable temperature control where opening and closing of furnace doors do not significantly affect the furnace temperature and the ingot temperature. As well, the reduction in the thickness of the FeGa materials during each rolling process was also carefully controlled. Controlled amount of deformation per pass, and controlled reheat between passes were used. All of this led to predictable and uniform deformation during warm rolling steps. In some aspects, the thickness reduction was controlled to range up to about 65% since cracking occurred above this level of reduction. In other aspects, the thickness reduction can range from about 45 to about 65%. In still other aspects, the thickness reduction can be about 50%. In yet other aspects, the thickness reduction in each rolling process was the same in each pass.

The warm rolling process is followed by another (or texture) annealing process. In this annealing process, the alloy is recrystallized and given a recrystallization-induced texture. Any annealing process that provides such a result can be used. Generally, the annealing process is performed for about 1 to about 24 hours at a temperature of about 900 to about 1300° C. In one aspect of the invention, the annealing process is performed for about 110 to about 130 minutes at a temperature of about 1125 to about 1175° C.

The element Be is a deadly poison and is also carcinogenic for humans since inhalation of Be dust causes severe and irreparable lung damage. Therefore, FeGa alloys containing Be were made using a different process. A DS FeGa ingot was first cast as known in the art. The ingots were then re-melted and allowed to flow into an inert tube (i.e., alumina) and encapsulate a predetermined amount of Be element that was already placed inside the tube. Because of the encapsulation of Be with the Fe or FeGa melt, as well as the short duration (such as about 1 to about 10 seconds) for the solidification of Fe and FeGa melt, Be vaporization was avoided during this encapsulation process.

The resulting mixture of FeGa and Be was then heated for a time and temperature sufficient to homogenize the mixture in a sealed tube (i.e., alumina) that has been evacuated and backfilled with a high-purity inert (i.e., argon) gas. The temperature of this stage can range from about 1400 to about 1500° C. In some aspects, this temperature can be about 1500° C. The time of this stage can range from about 1 to about 12 hours. In some embodiments, this time can be about 4 hours.

Then, the FeGaBe homogenized melt inside the same sealed tube was used for a directional growth process. The FeGaBe alloy is directionally grown at any suitable rate. Typically, this suitable rate can range from about 1 to about 225 mm/hour. In some aspects, this rate can be about 22.5 mm/hour. While the toxicity of Be requires exceptional care since its danger is next only to that of Pu, using this process allows safe manufacture Be containing Fe alloys with as much as 25 at. % Be.

The textured Fe—Ga alloys made using the above processes can provide an inexpensive and attractive alternative to existing rare-earth based magnetostrictive materials. These FeGa alloys can be cheaper to make than the corresponding single crystal or directionally-solidified textured materials and can be produced in larger quantities. Results from this work could be used to optimize the processing conditions for other alloys since FeGa, FeGaBe, and FeGaAl alloys: since they are single phase alloys with disordered solid solution phase (α-phase) with body centered cubic structure, these results could help optimize the warm deformation level, and the time and temperature of annealing for these alloys.

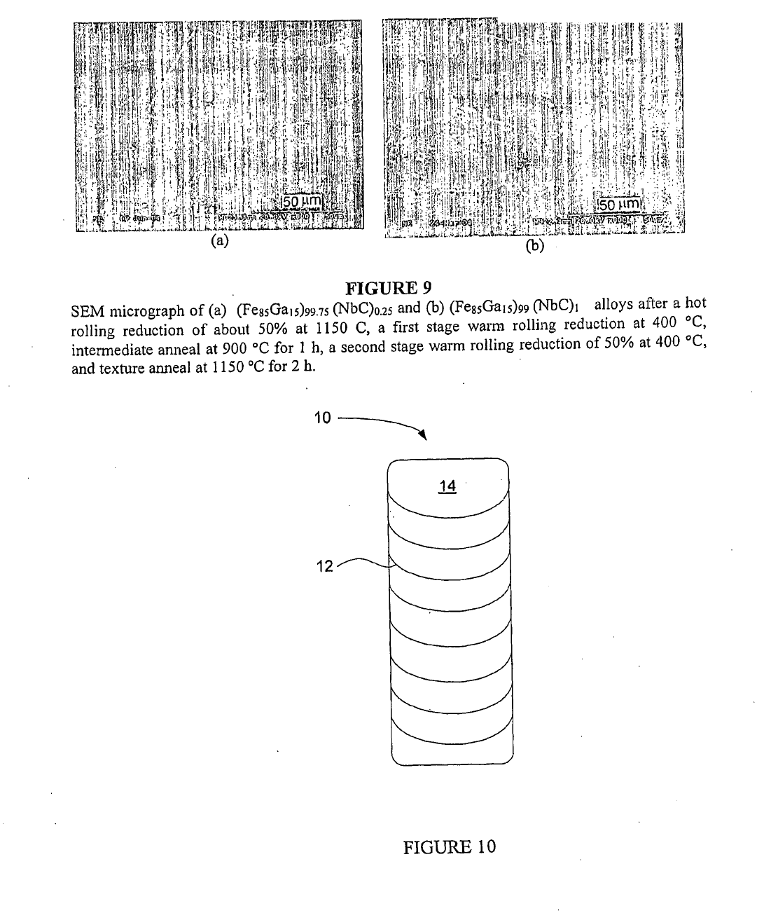

The alloys formed by these methods can be used for any purpose known in the art where magnetostrictive properties are desirable. Examples of such purposes include sensors, actuators, tuners, positioning systems, as well as those listed above. The alloys are used by making a device that takes advantage of the magnetostrictive properties. As shown in FIG. 10, a device 10 with electromagnetic winding 12 coiled about core 14 made substantially of the alloys of the invention. The device 10 operates in an actuator mode when current flowing through winding 12 generates a magnetic field that acts on core 14, causing dimensional changes along an axis of core 14. The device 10 also operates in a current generating mode when a force applied along an axis of core 14 changes the dimensions of the core 14, thereby changing the magnetic field to which the winding is exposed. The change in the magnetic field generates a current in the winding 12.

### EXAMPLE

(Fe₈₅Ga₁₅)₉₉(NbC)₁ and (Fe₈₅Ga₁₅)_{99.75}(NbC)_{0.25} alloy ingots, about 30 grams in weight, were prepared from high purity elements using an Edmund Beuhler® high-vacuum arc melting system. A Ti piece was first arc-melted to getter the oxygen and water molecules. The Fe and Ga were arc melted together using low and controlled power input and this resulted in negligible loss of Ga. Several of the 30 g alloy ingots were then melted together to form a 25 mm×25 mm×75mm block using a water-chilled copper mold. In these alloys, small amounts of NbC precipitates were added to control the grain size during deformation processing and annealing treatments.

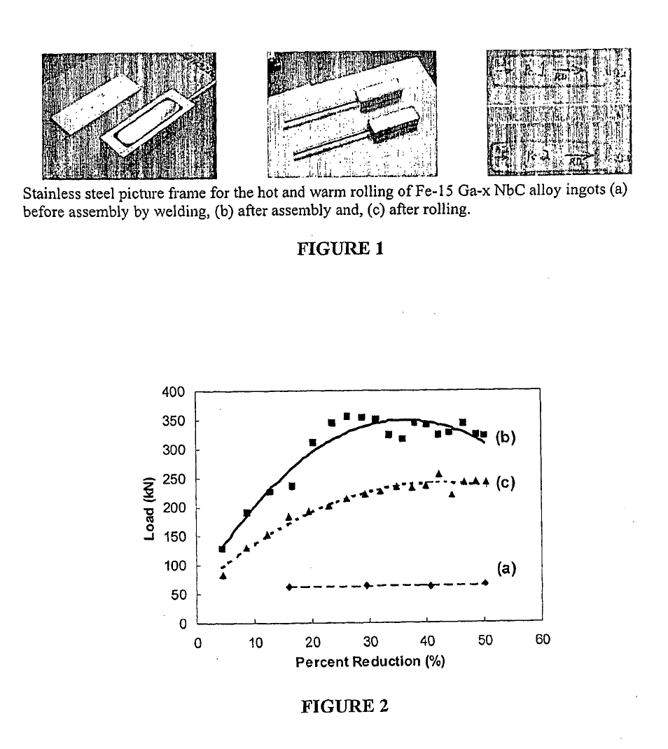

These large ingot blocks were wrapped in Ta foil and homogenized at 1200° C. in a Lindberg furnace under a flow of ultra high purity (UHP) argon. The ingots were machined and then encased in a machined stainless steel container that was then sealed with a 3.25 mm thick plate as shown in FIG. 1. This assembly allowed the strain through the thickness of the FeGa ingot to be more uniform and minimized the influence of chilling during hot and warm rolling operations that arises from the heat extraction by the contacting roll surface.

Next, a sequence of hot rolling at 1150° C. and a two-stage warm rolling at 400° C. with intermediate anneal at 900° C. for 1 hour was carried out. A large muffle furnace with a large heat capacity was used to heat and soak the alloy ingot encased in the stainless steel picture frame. Rolling load measurements were made during each pass using load cells. The ingots were hot rolled at 1150° C. by 50% to break down the cast structure, followed by a two-stage warm rolling at 400° C. with an intermediate anneal at 900° C. The reduction during each stage of warm rolling was 50% with each stage consisting of multiple passes of equal reduction. The ingots were reheated between passes.

Next, a texture anneal was performed and resulted in recrystallization and recrystallization induced texture. The stainless steel picture frame layers were removed from the ingots before texture annealing. The rolled materials were texture-annealed in the temperature range of 900° C. to 1300° C. for 1, 2, and 24 hours to identify the annealing temperature-time combination that can provide [001] textured material. After the texture-anneal, the ampoules containing the alloy samples were quenched in water.

Pole figure and inverse pole figure measurements were then carried out using a Hitachi® Environmental SEM S-3000N unit with TSL-EDAX™ orientation imaging microscopy (OIM™) attachment. A section normal to the rolling direction of each sample was scanned using a hexagonal grid with a step size of about 10 μm across a selected surface area of about 1180 μm×2600 μm. The electron backscatter diffraction patterns (EBSPs) and images were obtained at an accelerating voltage of 20 kV and a working distance of 12-15 mm. EBSP patterns formed on a phosphor screen were captured using a CCD camera, analyzed and stored using the OIM™ Data Collection software. The EBSPs contain several Kikuchi bands, which correspond to the diffraction planes of the sample. The angle between the bands, the width of the band and the intensities were used to index the pattern and determine the crystallographic orientation corresponding to each grid point. The crystalline orientation data corresponding to each pixel in the scan area was then analyzed the OIM™ Analysis software to obtain pole figures, inverse pole figures, grain orientation maps and other micro-texture information. An orthotropic symmetry was used for the rolled and annealed samples. Pole figures with and without the imposition of the orthotropic symmetry were examined and the use of orthotropic symmetry was found to be reasonable. The samples were prepared by careful polishing procedure that involved polishing using a series of grit papers down to 1200 paper, followed by polishing using 1, 0.3 and 0.05 mm alumina, and then chemo-mechanical polishing using colloidal silica.

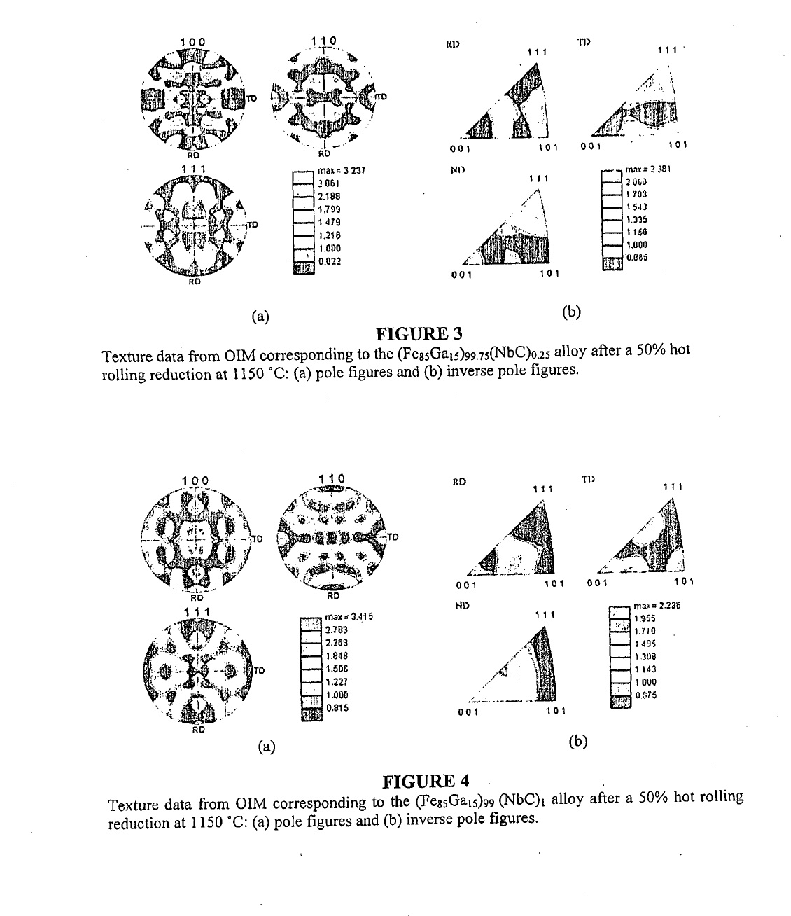

The evaluation of deformation loads during the various rolling operations was made using the load versus time charts obtained during the rolling of the ingots. Plots of the load versus % reduction for the hot rolling stage, first stage warm rolling, and second stage warm rolling are shown in FIG. 2 which are plots of loads during each pass versus the reduction at the end of the corresponding pass. Each stage of rolling consisted of multiple passes of equal reduction. The rolling loads were about 65 kN during hot rolling at 1150° C. The loads were higher during the first stage of warm rolling because of the finer NbC precipitation formed during hot rolling and subsequent cooling.

The plots in FIG. 2 show a substantial increase in load from about 130 kN at the beginning of the reduction to a maximum of about 350 kN towards the end of reduction, primarily due to the work hardening of the material. The loads decreased during the second stage of warm rolling to about 240 kN. The decrease in load during the second-stage warm rolling is most likely due to the coarsening of the NbC during intermediate annealing at 900° C.

Detailed microstructural evaluations were also carried out. The alloys showed good ductility and the values of rolling loads indicated that the processing of these alloys would not be very different from that of mild steel. The deformation loads observed during the rolling operations of the (Fe₈₅Ga₁₅)_{99.75}(NbC)_{0.25} alloy were typically lower than that for the (Fe₈₅Ga₁₅)₉₉(NbC)₁ alloy for a given condition.

The evolution of deformation and recrystallization-induced texture in polycrystalline (Fe₈₅Ga₁₅)₉₉(NbC)₁ and (Fe₈₅Ga₁₅)_{99.75}(NbC)_{0.25} alloys were made by examining the texture in the material after each stage of deformation, and after various subsequent recrystallization annealing treatments at different temperatures and time combinations. Fe-15 at. % Ga alloy composition lies within the bcc terminal solid solution phase region and, as expected, the x-ray diffraction patterns showed the α-phase (bcc) as their main phase. The mole fractions of NbC in these alloys were small and its presence could not be detected. The lattice parameter was about 2.898 Å, which is larger than that of pure iron, 2.866 Å.

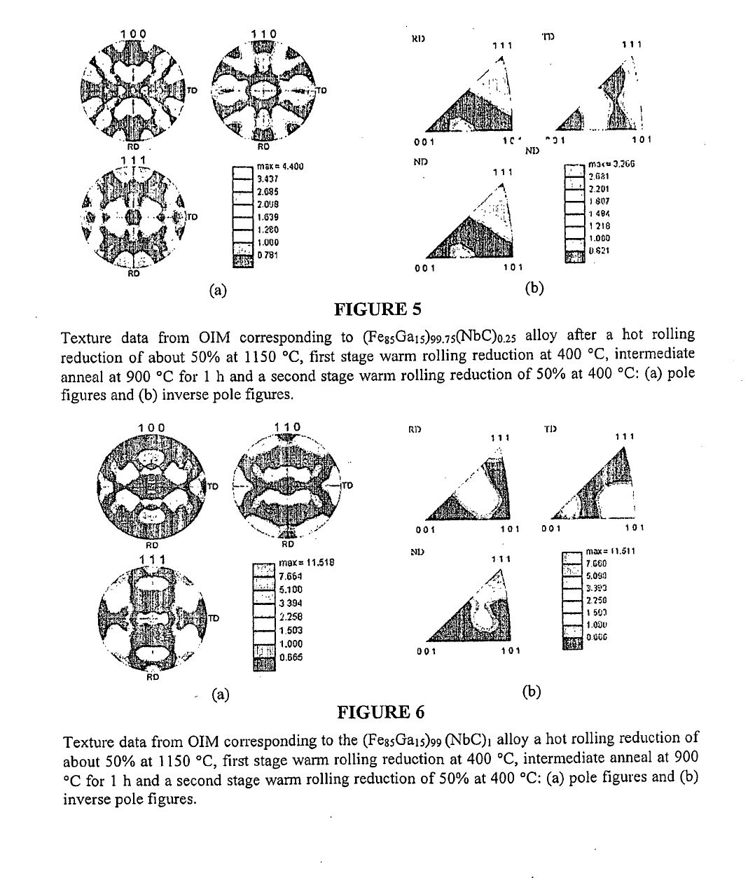

Evaluations of both (Fe₈₅Ga₁₅)₉₉(NbC)₁ and (Fe₈₅Ga₁₅)_{99.75}(NbC)_{0.25} under similar conditions of thermomechanical processing were performed to compare the influence of mole fraction of NbC on the development of texture in the polycrystalline alloy. FIG. 3 shows the pole figures and inverse pole figures corresponding to (Fe₈₅Ga₁₅)_{99.75}(NbC)_{0.25} alloy in the as-hot rolled condition. The grain orientation data presented in FIG. 3 corresponds to an examination of the surface normal to the rolling direction of the sample. Using color contour maps, the (001), (110), and (111) pole figures show the distribution of [001], [110], and [111] poles with respect to the rolling direction (RD), transverse direction (TD) and normal direction (ND) of the sample.

A combination of these three pole figure plots was then used to interpret the nature of texture in each sample. The inverse pole figure presents, in a stereographic projection, the distribution of specific sample directions relative to the crystal reference axis. Pole figures and inverse pole figures corresponding to as-hot rolled (Fe₈₅Ga₁₅)_{99.75}(NbC)_{0.25} alloy show a weak texture with a predominant component that lies between {hkl}<313> and {hkl}<110>, as can be seen in FIG. 3. Increasing the NbC content to 1 mol % resulted in a relatively weak texture with a stronger {hkl}<102> type component and a weaker {hkl}<001> component as can be seen from pole figures and inverse pole figures for the hot-rolled (Fe₈₅Ga₁₅)₉₉(NbC)₁ alloy illustrated in FIG. 4. The pole figures and inverse pole figures corresponding to (Fe₈₅Ga₁₅)_{99.75}(NbC)_{0.25} alloy after the second stage of warm rolling reduction of about 50% show a predominant {hkl}<212> type texture, as depicted in FIG. 5. The deformation induced texture in (Fe₈₅Ga₁₅)_{99(NbC)}₁ alloy after a two-stage warm rolling consists of a stronger {111}<112> texture as illustrated in FIG. 6.

The texture obtained after texture annealing of the (Fe₈₅Ga₁₅)_{99.75}(NbC)_{0.25} alloy at 1150° C. for 2 hours is shown in FIG. 7. The texture still shows mixed components but it changes from a strong as-second stage warm rolled {hkl><212> texture to a weak texture with stronger {hkl}<110> component and weaker {hkl}<113> component. However, increasing the NbC content in the Fe-15 at. % Ga alloy to 1 mole % of NbC resulted in a very strong {001}<100> preferred texture after texture anneal at 1150° C. for 2 hours, as shown in FIG. 8. This strong texture development is observed at a product thickness of 2.8 mm that is much larger than that typical in FeSi steel sheets.

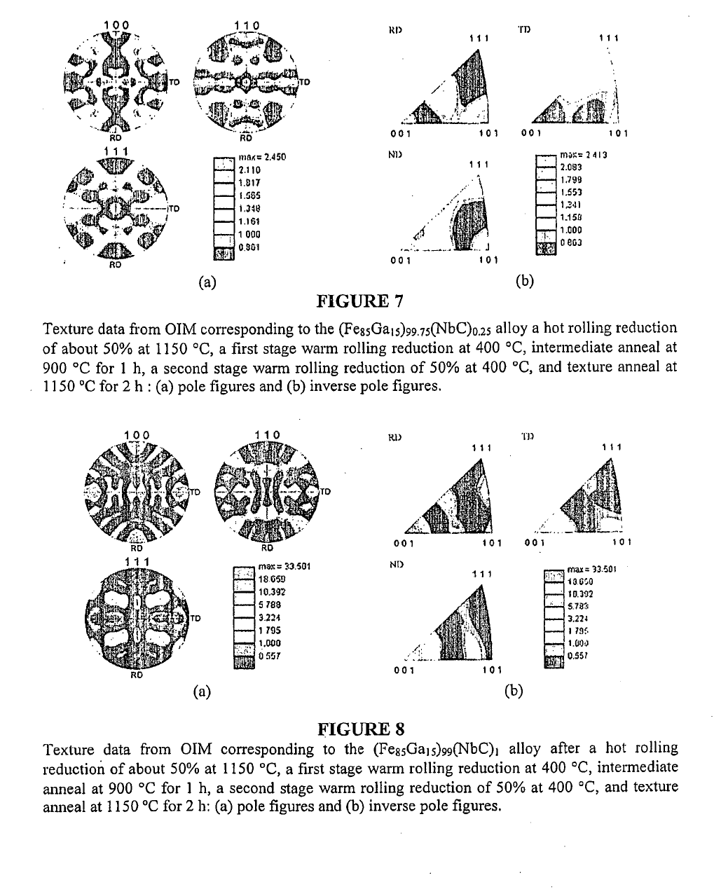

The optimal texture anneal temperature is lower and final grain sizes are smaller indicating the dominance of primary recrystallization. An SEM micrograph of (Fe₈₅Ga₁₅)_{99.75}(NbC)_{0.25} and (Fe₈₅Ga₁₅)₉₉(NbC)₁ alloys after texture anneal at 1150 ° C. for 2 h is shown in FIG. 9. The white specks observed in the micrographs are the NbC particles. The grain size of the alloy containing 1 mol. % NbC after texture anneal was also smaller than that for the 0.25 mol. % NbC alloy. The grain sizes observed were about 70 μm for 1% NbC alloy compared to about 110 μm for the 0.25 mol. % NbC alloy.

Thus, a sequence of hot rolling, two-stage warm rolling with intermediate anneal at 900° C. for 1 hour and extended final texture anneal at 1150° C. produces (Fe₈₅Ga₁₅)₉₉(NbC)₁ provided polycrystalline alloy material with a strong [001] preferred orientation along the rolling direction. Lowering the NbC content to 0.25 mol. % does not favor the development of [100] texture. This strong texture is observed at much higher thickness levels than in FeSi, indicating that the mechanism of texture development in this case is different. The deformation behavior during various rolling operations indicated moderate roll forces and good ductility for these alloys.

Having described these aspects of the invention, it is understood that the invention defined by the appended claims is not to be limited by particular details set forth in the above description, as many apparent variations thereof are possible without departing from the spirit or scope thereof.

We claim:

1. An alloy, comprising:
Fe in an amount more than about 67.5 at %;
Ga in an amount ranging up to about 32.5 at %; and
more than 1 mole % of a grain growth agent.

2. The alloy of claim 1, wherein the grain growth agent comprises NbC.

3. The alloy of claim 2, wherein the amount of NbC ranges from more than about 1 mole % to about 3 mole %.

4. The alloy of claim 1, having a Vickers hardness greater than about 5 in the texture.

5. The alloy of claim 4, wherein the Vickers hardness ranges from about 20 to about 40.

6. The alloy of claim 1, further comprising up to about 17 at % Al.

7. An alloy, comprising:
Fe in an amount more than about 67.5 at %;
Ga in an amount ranging up to about 32.5 at %; and
Be in an amount ranging up to about 25 at %.

8. The alloy of claim 7, wherein the amount of Be ranges from about 2.5 to about 22.5 at %.

9. The alloy of claim 8, wherein the amount of Be ranges from about 5 to about 15 at %.

10. The alloy of claim 7, further comprising up to about 3 mole % of a grain growth agent.

11. The alloy of claim 10, wherein the grain growth agent comprises NbC.

12. The alloy of claim 7, further comprising Al in an amount up to about 17 at %.

13. An alloy having the formula (Fe_{100-x-y-z}GaₓAl_{y}Be_{z})ₐ (NbC)_{b} wherein:
x is less than or equal to about 32.5;
y is less than or equal to about 17;
z is less than or equal to about 25;
a is more than or equal to about 97; and
b is less than or equal to about 3.

14. A device, comprising:
an alloy comprising Fe in an amount more than about 67.5 at %, Ga in an amount ranging up to about 32.5 at %, and Be in an amount ranging up to about 25 at %; and
an electrically conductive coil inductively coupled to the alloy.

15. The device of claim 14, wherein the amount of Be ranges from about 2.5 to about 7.5 at %.

16. A system for converting mechanical energy into electrical energy or electrical energy into mechanical energy, the system containing a device comprising:
an alloy comprising Fe in an amount more than about 67.5 at %, Ga in an amount ranging up to about 32.5 at %, and Be in an amount ranging up to about 25 at %; and
an electrically conductive coil inductively coupled to the alloy.

17. The system of claim 16, wherein the amount of Be ranges from about 2.5 to about 7.5 at %.

18. A method for making an alloy, comprising:
providing Fe in an amount more than about 67.5 at % and Ga in an amount ranging up to about 32.5 at %; and
adding more than 1 mole % of a grain growth agent to the alloy;
performing a hot rolling process;
performing a two-stage warm rolling process; and
performing an annealing process.

19. A method for making an alloy, comprising:
providing a melt containing Fe in an amount more than about 67.5 at % and Ga in an amount ranging up to about 32.5 at %;
using the melt to encapsulate Be;
heating the resulting mixture until it is substantially homogenized; and
directionally growing the homogenized mixture.

20. A method for making an alloy, comprising:
providing an alloy containing Fe in an amount more than about 67.5 at % and Ga in an amount ranging up to about 32.5 at %;
providing a protective sheath for the FeGa alloy;
performing a hot rolling process;
performing a two-stage warm rolling process; and
performing an annealing process.

21. The method of claim 20, wherein the protective sheath comprises stainless steel.

22. The method of claim 20, wherein the protective sheath has a thickness ranging from about 2 to about 4 mm.

23. The method of claim 20, further comprising providing the FeGa alloy with up to about 3 mole % of a grain growth agent.

24. The method of claim 20, wherein the protective sheath reduces the temperature loss of the surface of the FeGe alloy.

25. The method of claim 20, wherein the protective sheath maintains the temperature of the surface of the FeGe alloy near the operating temperature of the rolling processes.

26. The method of claim 20, further comprising removing the protective sheath before annealing.

27. An alloy, comprising:
Fe in an amount more than about 75 at %; and
Be in an amount ranging up to about 25 at %.

28. The alloy of claim 27, further comprising Al in an amount ranging up to about 17 at %.

29. The alloy of claim 27, further comprising Ga in an amount ranging up to about 32.5 at %.
